(19) United States
(12) Patent Application Publication
(10) Pub. No.: US 2017/0170265 A1
(43) Pub. Date: Jun. 15, 2017

(54) THICK GATE OXIDE FET INTEGRATED WITH FDSOI WITHOUT ADDITIONAL THICK OXIDE FORMATION

(71) Applicant: International Business Machines Corporation, Armonk, NY (US)

(72) Inventors: Anthony I-Chih Chou, Beacon, NY (US); Arvind Kumar, Beacon, NY (US); Sungjae Lee, Schenectady, NY (US)

(21) Appl. No.: 14/968,592

(22) Filed: Dec. 14, 2015

(51) Int. Cl. H01L 29/06; H01L 29/78; H01L 29/423; H01L 29/66

(52) U.S. Cl. CPC H01L 29/0649; H01L 29/66484; H01L 29/7831; H01L 29/42364

(57) ABSTRACT

A semiconductor structure formed based on a buried oxide (BOX) layer configured as a gate dielectric; a substrate adjacent to the BOX layer configured as a first gate electrode; a first source structure and a first drain structure, each residing above the BOX layer; a first channel structure residing between the first drain and first source structures; a second gate electrode residing above the first channel structure; a first shallow trench isolation (STI) structure and a second STI structure, each residing coplanar with and at opposite ends of the first source and first drain structures; and a second gate dielectric residing between the first channel structure and the second gate electrode, wherein a thickness of the second gate dielectric is less than a thickness of the BOX layer.

### BACKGROUND

Embodiments of the invention relate to semiconductor structures, in particular, for a thick-gate oxide field-effect transistor (FET) integrated with a fully-depleted silicon-on-insulator (FDSOI) structure without an additional thick-oxide formation.

Complementary metal-oxide semiconductor (CMOS) device fabrication with different gate dielectric thicknesses requires extra mask layer fabrication (one for each thickness), thereby increasing the resources and cost to produce.

### SUMMARY

Embodiments of the invention relate to semiconductor structures, in particular, for a thick-gate oxide field-effect transistor (FET) integrated with a fully-depleted silicon-on-insulator (FDSOI) structure without an additional thick-oxide formation and a method of manufacturing the same. In one embodiment, the semiconductor structure comprises a buried oxide (BOX) layer configured as a gate dielectric; a substrate adjacent to the BOX layer configured as a first gate electrode; a first source structure and a first drain structure, each residing above the BOX layer; a first channel structure residing between the first drain and first source structures; a second gate electrode residing above the first channel structure; a first shallow trench isolation (STI) structure and a second STI structure, each residing coplanar with and at opposite ends of the first source and first drain structures; and a second gate dielectric residing between the first channel structure and the second gate electrode, wherein a thickness of the second gate dielectric is less than a thickness of the BOX layer.

In one embodiment, the semiconductor structure further comprises a second drain structure residing above the BOX layer; a second channel structure residing between the first drain and second drain structures, wherein the first drain structure is configured as a source structure for the second drain structure.

In one embodiment of the present invention, the semiconductor structure further comprises a third gate electrode; a third gate dielectric residing between the second channel structure and the third gate electrode, wherein the third gate electrode resides above the second channel structure, the second and third gate dielectrics have a uniform thickness and a thickness of the third gate dielectric is less than a thickness of the BOX layer.

In one embodiment of the present invention, a method of forming the semiconductor structure comprises forming a buried oxide (BOX) layer configured as a gate dielectric; forming a substrate adjacent to the BOX layer configured as a first gate electrode; forming a first source structure and a first drain structure, each residing above the BOX layer. In this embodiment, the method further comprises forming a first channel structure residing between the first drain and first source structures; and forming a second gate electrode residing above the first channel structure, wherein a second gate dielectric resides between the first channel structure and the second gate electrode. In this embodiment, a thickness of the second gate dielectric is less than a thickness of the BOX layer.

In one embodiment, the method further comprises forming a second drain structure residing above the BOX layer; forming a second channel structure residing between the first source and second source structures; and forming a third gate electrode residing above the second channel structure, wherein a third gate dielectric resides between the second channel structure and the third gate electrode. In this embodiment, a thickness of the second and third gate dielectric is uniform and the thickness is less than a thickness of the BOX layer.

These and other features, aspects and advantages of the present invention will become understood with reference to the following description, appended claims and accompanying figures.

### BRIEF DESCRIPTION OF THE DRAWINGS

FIG. 1 is a cross-sectional view of an exemplary semiconductor structure comprising a thick-gate oxide field-effect, transistor (FET) integrated with a fully-depleted silicon-on-insulator (FDSOI) structure without an additional thick-oxide formation, according to one embodiment;

FIG. 2 is a cross-sectional view of an exemplary semiconductor structure comprising a thick-gate oxide field-effect transistor (FET) integrated with a fully-depleted silicon-on-insulator (FDSOI) structure without an additional thick-oxide formation, according to one embodiment;

FIG. 3 is a cross-sectional view of an exemplary semiconductor structure comprising a thick-gate oxide field-effect, transistor (FET) integrated with a fully-depleted silicon-on-insulator (FDSOI) structure without an additional thick-oxide formation, according to one embodiment; and

FIG. 4 illustrates a block diagram for a process for forming a thick-gate oxide field-effect transistor (FET) integrated with a fully-depleted silicon-on-insulator (FDSOI) structure without an additional thick-oxide formation, according to one embodiment.

### DETAILED DESCRIPTION

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

As used herein, a “lengthwise” element is an element that extends along a corresponding lengthwise direction, and a “widthwise” element is an element that extends along a corresponding widthwise direction.

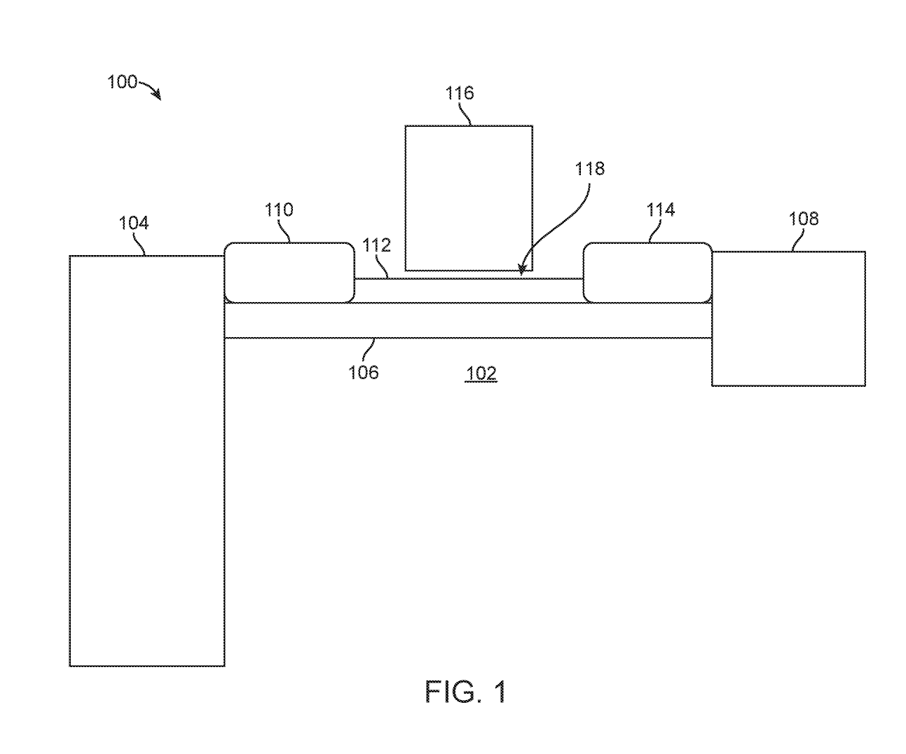

FIG. 1 is a cross-sectional view of an exemplary semiconductor structure 100 comprising a thick-gate oxide FET integrated with a FDSOI structure without an additional thick-oxide formation, according to one embodiment of the present invention. In this embodiment, the semiconductor structure 100 comprises a buried oxide (BOX) layer 106 configured as a gate dielectric and a substrate 102 adjacent to the BOX layer configured as a first gate electrode. The structure 100 further comprises a first source structure 110 and a first drain structure 114, each residing above the BOX layer 106. The structure 100 also comprises a first channel structure 112 residing between the first source structure 110 and first drain structure 114. The structure 100 further comprises a second gate electrode 116 residing above the first channel structure 112; a first shallow trench isolation (STI) structure 104 and a second STI structure 108, each residing coplanar with and at opposite ends of the first source structure 110 and first drain structure 114. In this embodiment of the present invention, a second gate dielectric 118 resides between the first channel structure 112 and the second gate electrode 116. A thickness of the second gate dielectric 118 is less than a thickness of the BOX layer 106. In this embodiment of the present invention, the BOX layer 106 is a thin BOX (e.g. 3-7 nm) combined with the substrate 102 to form a thick-oxide device without the overhead of creating additional masking layers between the first and second gates.

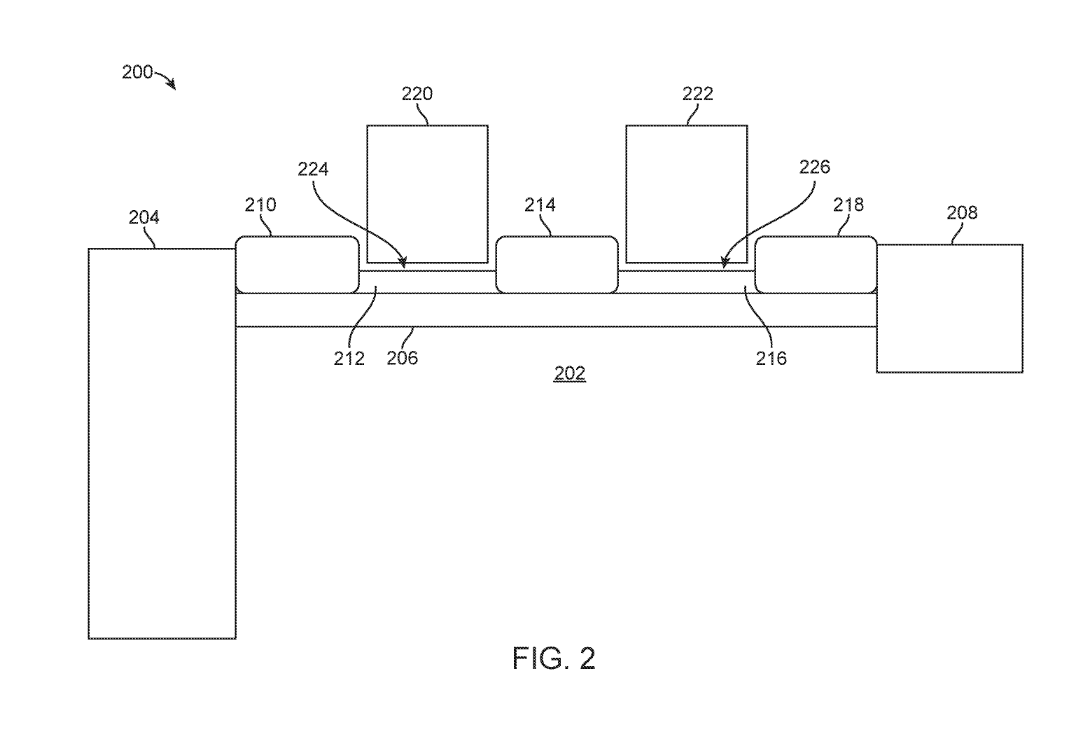

FIG. 2 is a cross-sectional view of an exemplary semiconductor structure 200 comprising a thick-gate oxide FET integrated with a FDSOI structure without an additional thick-oxide formation, according to one embodiment of the present invention. In this embodiment, the semiconductor structure 200 comprises a buried oxide (BOX) layer 206 configured as a gate dielectric and a substrate 202 adjacent to the BOX layer configured as a first gate electrode. The structure 200 further comprises a first source structure 210 and a first drain structure 214, each residing above the BOX layer 206. The structure 200 also comprises a second drain structure 218 also residing above the BOX layer 206. In this embodiment, the first drain structure 214 acts as a second source structure for the second drain structure 218.

The structure 200 further comprises a first channel structure 212 residing between the first source structure 210 and first drain structure 214. A second channel structure 216 resides between the first drain structure 214 and the second drain structure 218. The structure 200 further comprises a second gate electrode 220 residing above the first channel structure 212 and a third gate electrode 222 residing above the second channel structure 216. The embodiment also comprises a first STI structure 204 and a second STI structure 208, each residing coplanar with and at opposite ends of the first source structure 210 and second drain structure 218.

In this embodiment of the present invention, a second gate dielectric 224 resides between the first channel structure 212 and the second gate electrode 220 while a third gate dielectric 226 resides between the second channel structure 216 and the third gate electrode 222. The thickness of the second and third gate dielectrics is uniform. Further, the thickness of the second gate dielectric 224 and third gate dielectric 226 is less than a thickness of the BOX layer 206.

In this embodiment of the present invention, the third gate electrode 222 is a biased cascode gate, while the second gate electrode 220 is a floating gate. In this configuration, the first gate electrode 202 controls the first channel structure 212, and the third gate electrode 222 electrically dominates over the first gate electrode 202 to control the second channel structure 216 because the thickness of the third gate dielectric 226 is thinner than the thickness of the BOX layer 206. Also in this configuration, the first channel structure 212 typically has longer channel length as thick-oxide FET (controlled by the first gate electrode 202), connected in series with the second channel structure 216 as thin-oxide FET (controlled by the third gate electrode 226), thus making the cascode device with high output impedance.

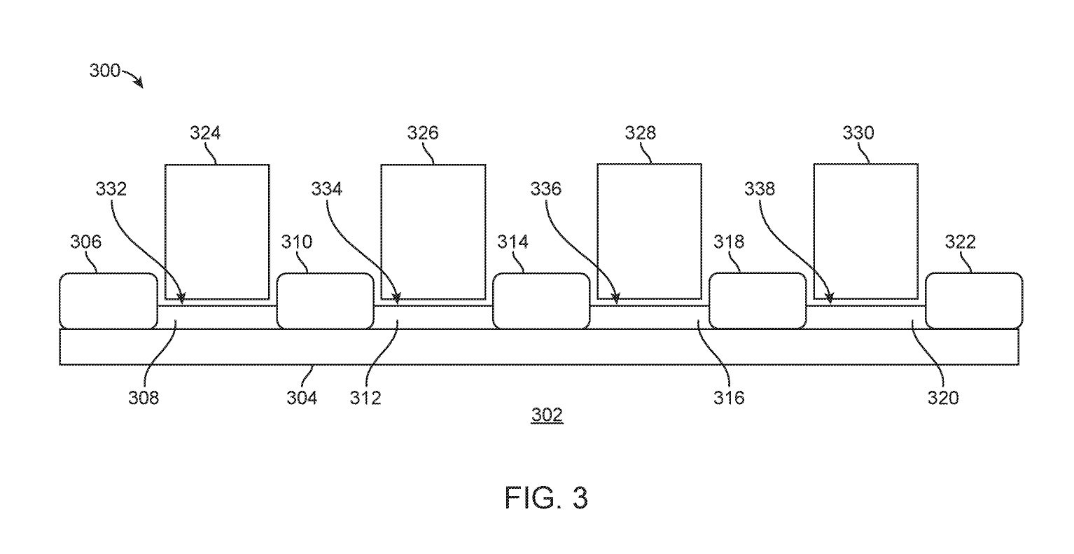

FIG. 3 is a cross-sectional view of an exemplary semiconductor structure 300 comprising a thick-gate oxide FET integrated with a FDSOI structure without an additional thick-oxide formation, according to one embodiment of the present invention. In this embodiment, the semiconductor structure 300 comprises a buried oxide (BOX) layer 304 configured as a gate dielectric and a substrate 302 adjacent to the BOX layer configured as a first gate electrode. The structure 300 further comprises a source structure 314, a first drain structure 310, a second drain structure 318, a first output structure 306 and a second output structure 322. In this embodiment, the source structure 314 resides above and towards the center of the BOX layer 304. The first drain structure 310 and second drain structure 318 reside on opposite sides of the source structure 314. The first output structure 306 resides above the BOX layer 304 such that the first drain structure 310 resides between the first output structure 306 and the source structure 314. Similarly, the second output structure 322 resides above the BOX layer 304 such that the second drain structure 318 resides between the second output structure 322 and the source structure 314.

In this embodiment of the present invention, the semiconductor structure 300 further comprises a first channel structure 308 residing between the first output structure 306 and the first drain structure 310. A second channel structure 312 resides between the first drain structure 310 and the source structure 314. A third channel structure 316 resides between the source structure 314 and the second drain structure 318. Finally, a fourth channel structure 320 resides between the second drain structure 318 and the second output structure 322.

This embodiment further comprises a second gate dielectric 332 residing between the first channel structure 308 and a second gate electrode 324. A third gate dielectric 334 resides between the second channel structure 312 and a third gate electrode 326. A fourth gate dielectric 336 resides between the third channel structure 316 and a fourth gate electrode 328. Further, a fifth gate dielectric 338 resides between the fourth channel structure 320 and a fifth gate electrode 330. In this configuration, the second gate electrode 324 is a switch P gate, the third gate electrode 326 and fourth gate electrode 328 electrodes are floating gates, while the fifth gate electrode 330 is a switch N gate.

In one embodiment of the present invention, the thickness of each of the second, third, fourth and fifth gate dielectrics is uniform for thin-oxide FET. Further, the gate dielectric thickness is less than the thickness of the BOX layer 304. In this configuration, the floating gates (third 326 and fourth 328 gate electrodes) are not electrically biased and thus, will not have control over the second channel 312 and third channel 316 structures. Also in this configuration, the first drain structure 310 and the second drain structure 318 are electrically connected; hence, making the second channel 312 and third channel 316 structures be connected in parallel and controlled by the first gate electrode 302. Turning on the switch P gate or the second gate electrode 324 and turning off the switch N gate or the fifth gate electrode 330 will make current flow from the source structure 314 towards the first output structure 306. Conversely, electrically turning on the switch N gate or the fifth gate electrode 330 and turning off the switch P gate or the second gate electrode 324 will make current flow from the source structure 314 towards the second output structure 322.

In one embodiment of the present invention, semiconductor structure 300 is configured as a current-steering digital-to-analog (DAC) device. In this embodiment, the structure 300 may comprise a thick-oxide FET as the current source and thin-oxide FETs to steer current towards the first output structure 306 or the second output structure 322, and each output structure is connected to output resistor; hence, resulting in differential output voltages at the DAC output.

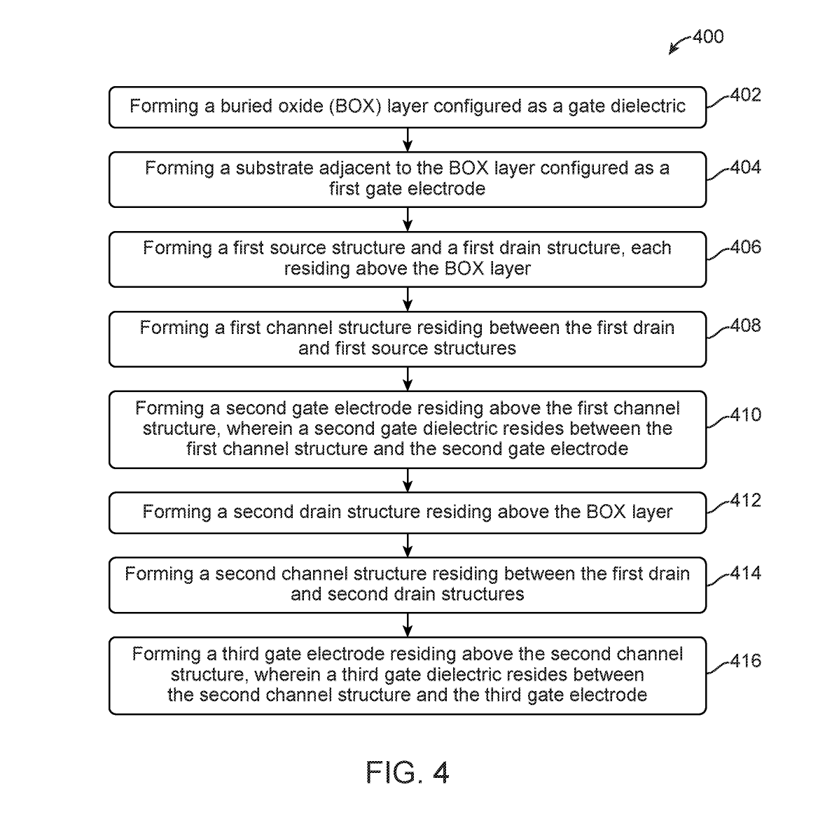

FIG. 4 illustrates a block diagram for a process 400 for forming a thick-gate oxide FET integrated with a FDSOI structure without an additional thick-oxide formation, according to one embodiment. In this embodiment of the present invention, the method of formation 400 comprises forming 402 a buried oxide (BOX) layer configured as a gate dielectric; and forming 404 a substrate adjacent to the BOX layer configured as a first gate electrode.

The method 400 further comprises the step 406 of forming a first source structure and a first drain structure, each residing above the BOX layer. This embodiment also comprises the step 408 of forming a first channel structure residing between the first drain and first source structures; and step 410 of forming a second gate electrode residing above the first channel structure, wherein a second gate dielectric resides between the first channel structure and the second gate electrode. In one embodiment of the present invention, a thickness of the second gate dielectric is less than a thickness of the BOX layer.

In this embodiment, the method 400 further comprises the step 412 of forming a second drain structure residing above the BOX layer; the step 414 of forming a second channel structure residing between the first drain and second drain structures; and step 416 of forming a third gate electrode residing above the second channel structure, wherein a third gate dielectric resides between the second channel structure and the third gate electrode. In this embodiment of the present invention, a thickness of the second and third gate dielectric is uniform and the thickness is less than a thickness of the BOX layer.

The exemplary methods and techniques described herein may be used in the fabrication of IC chips. In one embodiment, the IC chips may be distributed by a fabricator in raw wafer form (i.e., as a single wafer that has multiple unpackaged IC chips), as a bare die, or in a packaged form. In the latter case, the IC chip is mounted in a single IC chip package (e.g., a plastic carrier with leads that are affixed to a motherboard or other higher level carrier) or in a multi-IC chip package (e.g., a ceramic carrier that has either or both surface interconnections or buried interconnections). The IC chip is then integrated with other IC chips, discrete circuit elements and/or other signal processing devices as part of either (a) an intermediate product, such as a motherboard, or (b) an end product, such as microprocessors, smart phones, mobile phones, cellular handsets, set-top boxes, DVD recorders and players, automotive navigation, printers and peripherals, networking and telecom equipment, gaming systems, toys and digital cameras, as non-limiting examples. One or more embodiments may be applied in any of various highly integrated semiconductor devices.

Unless described otherwise or in addition to that described herein, “depositing” may include any now known or later developed techniques appropriate for the material to be deposited, including, but not limited to: CVD, LPCVD, PECVD, semi-atmosphere CVD (SACVD), high density plasma CVD (HDPCVD), rapid thermal CVD (RTCVD), ultra-high vacuum CVD (UHVCVD), limited reaction processing CVD (LRPCVD), metalorganic CVD (MOCVD), sputtering deposition, ion beam deposition, electron beam deposition, laser assisted deposition, thermal oxidation, thermal nitridation, spin-on methods, PVD, ALD, chemical oxidation, MBE, plating or evaporation. Any references to “poly” or “poly silicon” should be understood to refer to polycrystalline silicon.

References herein to terms such as “vertical”, “horizontal,” etc. are made by way of example, and not by way of limitation, to establish a frame of reference. The term “horizontal” as used herein is defined as a plane parallel to the conventional plane or surface of the substrate, regardless of the actual spatial orientation of the semiconductor substrate. The term “vertical” refers to a direction perpendicular to the horizontal, as just defined. Terms, such as “on,” “above,” “below,” “side” (as in “sidewall”), “higher,” “lower,” “over,” “beneath” and “under,” are defined with respect to the horizontal plane. It is understood that various other frames of reference may be employed for describing one or more embodiments without departing from the spirit and scope of the one or more embodiments.

References in the claims to an element in the singular is not intended to mean “one and only” unless explicitly so stated, but rather “one or more.” All structural and functional equivalents to the elements of the above-described exemplary embodiment that are currently known or later come to be known to those of ordinary skill in the art are intended to be encompassed by the present claims. No claim element herein is to be construed under the provisions of 35 U.S.C. section 112, sixth paragraph, unless the element is expressly recited using the phrase “means for” or “step for.”

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, steps, operations, elements, materials, and/or components, but do not preclude the presence or addition of one or more other features, steps, operations, elements, materials, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

1: A structure, comprising:
a thick-gate oxide field effect transistor (FET) comprising:
a buried oxide (BOX) layer configured as a first gate dielectric; and
a substrate directly adjacent to and combined with the BOX layer, the substrate configured as a first gate electrode for controlling the thick-gate oxide FET; and
a thin-gate oxide FET comprising a second gate dielectric residing over the thick-gate oxide FET.

2: The structure of claim 1, further comprising a first source structure and a first drain structure, the first source structure and the first drain structure residing above the BOX layer.

3: The structure of claim 2, wherein the thick-gate oxide FET further comprises a first channel structure residing above the BOX layer and extending between the first drain structure and the first source structure.

4: The structure of claim 3, further comprising a second gate electrode residing above the first channel structure.

5: The structure of claim 4, wherein the first gate electrode comprises a first shallow trench isolation (STI) structure and a second STI structure, each STI structure residing coplanar with and at opposite ends of the first source structure and the first drain structure.

6: The structure of claim 5, wherein the second gate dielectric resides between the first channel structure and the second gate electrode.

7: The structure of claim 6, wherein a thickness of the second gate dielectric is less than a thickness of the BOX layer.

8: The structure of claim 7, further comprising a second drain structure residing above the BOX layer.

9: The structure of claim 8, wherein the thin-gate oxide FET further comprises a second channel structure residing above the BOX layer and extending between the first drain structure and the second drain structure the second channel structure connected in series with the first channel structure, and the first channel structure having a longer channel length than the second channel structure.

10: The structure of claim 9, wherein the first drain structure is configured as a source structure for the second drain structure.

11: The structure of claim 10, further comprising a third gate electrode for controlling the thin-gate oxide FET.

12: The structure of claim 11, wherein the third gate electrode resides above the second channel structure.

13: The structure of claim 12, wherein the thin-gate oxide FET further comprises a third gate dielectric residing between the second channel structure and the third gate electrode.

14: The structure of claim 13, wherein the second gate dielectric and the third gate dielectric have a uniform thickness.

15: The structure of claim 14, wherein a thickness of the third gate dielectric is less than a thickness of the BOX layer.

16: A method, comprising:
forming a buried oxide (BOX) layer configured as a first gate dielectric;
forming a first gate electrode comprising:
a substrate adjacent to the BOX layer;
a first shallow trench isolation (STI) structure; and
a second STI structure; and
forming a first source structure and a first drain structure, each residing above the BOX layer;
wherein the first STI structure and second STI structure reside coplanar with and at opposite ends of the first source and first drain structures.

17: The method of claim 16, further comprising:
forming a first channel structure residing between the first drain and first source structures; and
forming a second gate electrode residing above the first channel structure, wherein a second gate dielectric resides between the first channel structure and the second gate electrode.

18: The method of claim 17, wherein a thickness of the second gate dielectric is less than a thickness of the BOX layer.

19: The method of claim 18, further comprising:
forming a second drain structure residing above the BOX layer;
forming a second channel structure residing between the first drain and second drain structures; and
forming a third gate electrode residing above the second channel structure,
wherein a
third gate dielectric resides between the second channel structure and the third gate electrode.

20: The method of claim 19, wherein a thickness of the second and third gate dielectric is uniform and the thickness is less than a thickness of the BOX layer.
